(19) United States
(12) Patent Application Publication
(10) Pub. No.: US 2005/0126622 A1
(43) Pub. Date: Jun. 16, 2005

(54) Solar cell module and method of producing the same

(75) Inventors: Takaaki Mukai, Hikone-shi (JP); Shigenori Itoyama, Sakata-gun (JP); Ichiro Kataoka, Hikone-shi (JP); Hidehisa Makita, Hikone-shi (JP); Masaaki Matsushita, Hikone-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/000,088

(22) Filed: Dec. 1, 2004

(30) Foreign Application Priority Data
Dec. 11, 2003 (JP) 2003-413072

(51) Int. Cl. H01L 25/00

(52) U.S. Cl. 136/251

(57) ABSTRACT

To provide a solar cell module and a method of producing the same capable of improving mechanical strength as well as providing less weight and high productivity. The solar cell module includes: a solar cell panel in which a photovoltaic device for performing photoelectric conversion is sealed with a covering material; a plurality of reinforcing members which are in contact with a back of the solar cell panel; a perpendicular portion formed on an opposed end portion of each of the reinforcing members at least along one of a longitudinal direction and a width direction of the solar cell panel as well as extended with respect to an installation portion of a structure; and a frame provided on an opposed end portion of the solar cell panel perpendicular to the perpendicular portion of the reinforcing member.

### BACKGROUND OF THE INVENTION

1. Field of the Invention

The present invention relates to a solar cell module and a method of producing the same, and more particularly, the present invention relates to a solar cell module which includes reinforcing members on a back of a solar cell panel.

2. Related Background Art

Solar energy is clean and inexhaustible energy and therefore it draws increasing attention year by year with depletion of fossil fuels and aggravation of environmental problems. At present, solar power generation systems utilizing solar energy for power generation are installed on various places such as general housing roofs and high-rise building walls.

FIG. 17 is a top plan view showing an example of a conventional solar cell module which has been widely spread in the market, and FIG. 18 is a cross-sectional view taken along the line 18-18 in FIG. 17. In those figures, reference numeral 10 denotes a photovoltaic device, 11 denotes a covering material, 12 denotes a reinforcing member, and 13 denotes a frame. As shown in the figures, a conventional solar cell module includes a plurality of photovoltaic devices 10, a covering material 11 which seals each of the photovoltaic devices 10, a reinforcing member 12 which provides mechanical strength to avoid damaging the photovoltaic devices 10 from outside shock which they may receive during or after installation, and a frame 13 which covers end portions of the solar cell module and also serves as a fixing tool when fixing to a base for example. A back of the photovoltaic devices set sealed with the covering material 11 is reinforced with the plate-shaped reinforcing member 12 and such a laminated body is supported on and fixed to the frame 13.

Sizes of such solar cell modules are so diverse, however, a solar cell module having a large area with large production of electricity for each solar cell module is often used in the case of a comparatively large installing area such as a power station or a roof of public facilities. The reason is that, in the case of the same output, it provides less work in electrical connection between solar cell modules, less work in fixing a solar cell module to a base, or. less cost for each watt of a solar cell module.

In contrast, a solar cell module with a large area receives larger strength, which may be exerted in strong winds or snow coverage, than that received by a solar cell module with a small area, and therefore solar cell modules of each maker are devised by all kinds of things to improve mechanical strength against such external stresses. A technique that improves mechanical strength of a solar cell module by providing an angle with an L-shaped cross-section on a back of the solar cell module is described in Japanese Patent Application Laid-Open No. H08-49377. A technique that improves mechanical strength of a solar cell module by using reinforced glass is also described in Japanese Patent Application Laid-Open No. H06-310748. Measures to increase the thickness of a reinforcing member such as glass or metal plate can be used instead of such techniques.

When mechanical strength of a solar cell module is improved with such techniques that increases the thickness of the reinforcing member provided on the back of the solar cell module or provides the angle with an L-shaped cross-section as described in Japanese Patent Application Laid-Open No. H08-49377, a weight of the solar cell module itself increases, thereby causing a worker's burden to increase in carrying and installing work, whereby there arises a problem in that work efficiency decreases. Moreover, when the weight of the solar cell module itself increases owing to increase in thickness of the reinforcing member etc., there also arises a problem in that a load exerted on a structure such as a roof or a wall on which the solar cell module is installed increases.

In addition, the use of a high mechanical strength material such as the reinforced glass as the reinforcing member as described in Japanese Patent Application Laid-Open No. H06-310748 can avoid to increase a weight of a solar cell module. However, the reinforced glass is used for special applications and is expensive because of less circulation in the market and therefore it is not preferable since the use causes the solar cell module to increase its manufacturing cost.

Further, when the reinforcing member of the solar cell module is composed of one sheet of glass or a metal plate, external stresses exerted on the solar cell module concentrate on the end side midsections of the reinforcing member. Consequently, the material and thickness of the reinforcing member have to be selected based on the end side midsections. However, the selection provides the rest of the end side midsections with excessive mechanical strength. This is very useless.

### SUMMARY OF THE INVENTION

The present invention has been made to solve the aforementioned problems, and an object of the present invention is to provide a solar cell module and a method of producing the same which can improve mechanical strength and provide less weight and high productivity.

In order to achieve the above object, according to one aspect of the present invention, there is provided solar cell module, including: a solar cell panel in which a photovoltaic device for performing photoelectric conversion is sealed with a covering material; a plurality of reinforcing members which are in contact with a back of the solar cell panel; a perpendicular portion formed on an opposed end portion of each of the reinforcing members at least along one of a longitudinal direction and a width direction of the solar cell panel as well as extended with respect to an installation portion of a structure; and a frame provided on an opposed end portion of the solar cell panel perpendicular to the perpendicular portion of the reinforcing member.

In further aspect of the solar cell module, the perpendicular portion of the reinforcing member is preferably formed by bending.

In further aspect of the solar cell module, the perpendicular portion of the reinforcing member on one side is preferably in contact with the perpendicular portion of the reinforcing member on the other side in two adjacent reinforcing members.

In further aspect of the solar cell module, the solar cell panel preferably includes a photovoltaic device set which is obtained by electrically connecting at least one photovoltaic device.

In further aspect of the solar cell module, the frame is preferably provided on only the end portion on the long side or the end portion on the short side of the solar cell module.

In further aspect of the solar cell module, the frame preferably includes an insertion portion into which the solar cell panel is inserted.

In further aspect of the solar cell module, a part of the insertion portion preferably includes a cutout into which the perpendicular portion of the reinforcing member is inserted.

In further aspect of the solar cell module, it is preferable that the solar cell panel include at least one bypass diode and the bypass diode be inserted into the insertion portion of the frame.

In further aspect of the solar cell module, the solar cell panel and the reinforcing member are preferably fixed with an adhesive or a double-side adhesive tape.

In further aspect of the solar cell module, it is preferable that the solar cell panel has a light-receiving surface and a non-light-receiving surface and at least one of the light-receiving surface and the non-light-receiving surface be sealed with the covering material.

According to another aspect of the present invention, there is provided a method of producing a solar cell module which includes a plurality of reinforcing members with perpendicular portions on a back of a solar cell panel in which photovoltaic devices for performing photoelectric conversion are sealed with a covering material, the method including the steps of: forming the solar cell panel; forming an installation surface of the solar cell panel by placing a plurality of the reinforcing members with the perpendicular portions; and installing the solar cell panel on the installation surface.

In further aspect of the method of producing a solar cell module, the step of forming the solar cell panel preferably includes a step of sealing a photovoltaic device set which is composed of an electrically connected single photovoltaic device or a plurality of the photovoltaic devices with a covering material.

In further aspect of the method of producing a solar cell module, the method preferably further includes a step of inserting the frame into the end portion of the solar cell module after the step of installing the solar cell panel on the installation surface.

In further aspect of the method of producing a solar cell module, wherein the frame is preferably provided on only the end portion on the long side or the end portion on the short side of the solar cell module in the step of inserting the frame into the end portion of the solar cell module.

According to the present invention, the solar cell module includes a plurality of reinforcing members which are in contact with a back of a solar cell panel, each reinforcing member provides a perpendicular portion which is formed on the opposed end portion along a longitudinal or width direction of the solar cell panel as well as extended with respect to an installation surface of a structure, and consequently a number of perpendicular portions are arranged on the back of the solar cell panel. As a result, mechanical strength is improved in comparison with a solar cell module provided with a tabular reinforcing member. Moreover, as the mechanical strength of the reinforcing member increases by forming the perpendicular portions, the thickness of the reinforcing member can be reduced, thereby permitting the solar cell module to reduce its weight. In addition, frames are installed on the opposed end portions of the solar cell panel perpendicular to the perpendicular portions of the reinforcing members so that the mechanical strength of the solar cell module significantly increases.

That is, a solar cell module and a method of producing the same can offer advantages in improving mechanical strength as well as providing less weight and high productivity.

Other features and advantages of the present invention will be apparent from the following description taken in conjunction with the accompanying drawings.

### BRIEF DESCRIPTION OF THE DRAWINGS

FIG. 1 is a top plan view seen from a light-receiving surface side showing a solar cell module according to an embodiment of the present invention;

FIG. 2 is a rear view seen from a non-light-receiving surface side showing the solar cell module according to the embodiment;

FIG. 3 is a cross-sectional view taken along the line 3-3 in FIG. 1;

FIG. 4 is a top plan view seen from a light-receiving surface side showing a solar cell module according to an embodiment of the present invention;

FIG. 5 is a rear view seen from a non-light-receiving surface side showing the solar cell module according to the embodiment;

FIG. 6 is a cross-sectional view taken along the line 6-6 in FIG. 4;

FIG. 7 is a cross-sectional view taken along the line 7-7 in FIG. 4;

FIG. 8 is an electrical connection diagram for explaining a solar cell module according to the example;

FIG. 9 is a perspective view showing a reinforcing member used in a solar cell module according to the example;

FIG. 10 is a top plan view seen from a light-receiving surface side showing a solar cell panel according to the example;

FIG. 11A is a rear view seen from a non-light-receiving surface side showing the solar cell panel according the example, and FIG. 11B is an enlarged view showing a main part encircled in FIG. 11A;

FIG. 12 is a cross-sectional view taken along the line 12-12 in FIG. 10;

FIG. 13 is a top plan view seen from a light-receiving surface side showing a photovoltaic device according to the example;

FIG. 14 is a rear view seen from a non-light-receiving surface side showing the photovoltaic device according to the example;

FIG. 15 is a cross-sectional view taken along the line 15-15 in FIG. 13;

FIG. 16 is a perspective view showing an assembling structure of a solar cell module according to the embodiment;

FIG. 17 is a top plan view showing an example of a conventional solar cell module; and

FIG. 18 is a cross-sectional view taken along the line 18-18 in FIG. 17.

### DESCRIPTION OF THE PREFERRED EMBODIMENTS

Best embodiments for carrying out the present invention will be described below with reference to the accompanying drawings. However, the present invention is not limited to these embodiments.

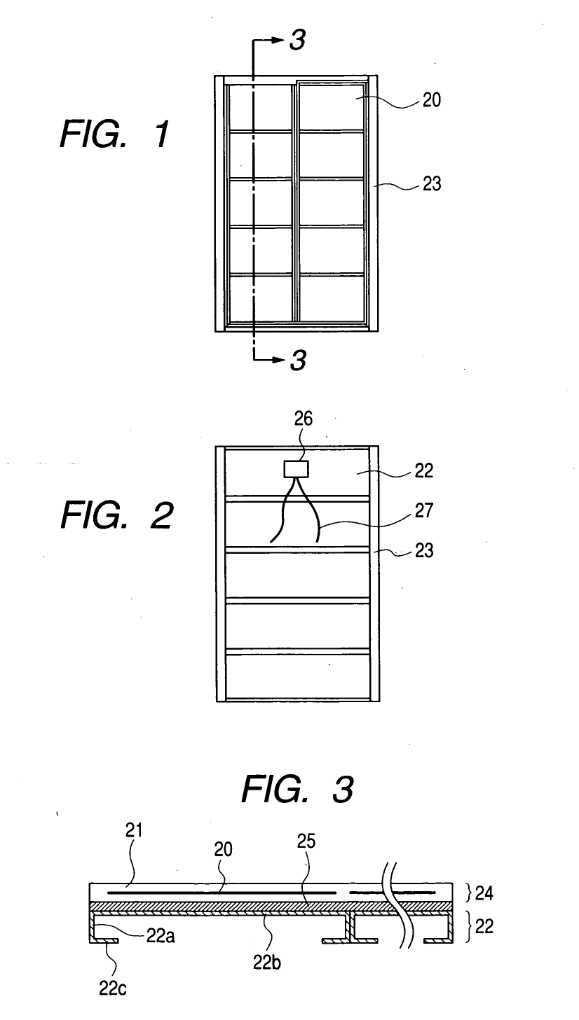

FIG. 1 is a top plan view seen from a light-receiving surface side showing a solar cell module according to an embodiment of the present invention and FIG. 2 is a rear view seen from a non-light-receiving surface side showing the solar cell module according to the embodiment. FIG. 3 is a cross-sectional view taken along the line 3-3 in FIG. 1. In those figures, reference numeral 20 denotes a photovoltaic device, 21 denotes a covering material, 22 denotes a reinforcing member, 22a denotes a perpendicular portion, 22b denotes an installation surface, 22c denotes a turnback portion, 23 denotes a frame, 24 denotes a solar cell panel, 25 denotes an adhesive, 26 denotes a junction box, and 27 denotes an output cable.

As shown in the figures, the solar cell module according to the present invention includes a plurality of the reinforcing members 22 which are in contact with a back of the solar cell panel 24 in which the photovoltaic device 20 for performing a photoelectric conversion is sealed with the covering material. Each reinforcing member 22 provides the perpendicular portion 22a which is formed on the opposed end portions along a longitudinal or width direction of the solar cell panel 24 as well as extended with respect to an installation portion of a structure such as a roof or a wall. The solar cell module includes the frame 23 provided on the opposed end portions of the solar cell panel 24 perpendicular to the perpendicular portion 22a of the reinforcing member 22. In this embodiment, the perpendicular portion 22a of the reinforcing member 22 is formed along the width direction of the solar cell panel 24, the frame 23 is provided on the end portion on the long side of the solar cell panel 24, and the reinforcing member 22 is inserted into the frame 23 so that the perpendicular portion 22a of the reinforcing member 22 is arranged perpendicular to the frame 23.

A plurality of the reinforcing members 22 having the perpendicular portions 22a mentioned above are placed in the installation portion of the structure so that the adjacent perpendicular portions 22a of the reinforcing members contact each other, and an installation surface 22b of the solar cell panel 24 is provided on those reinforcing members 22.

The solar cell panel 24 is fixed to the above-mentioned installation surface 22b with a double-side adhesive tape or adhesive.25. The above-mentioned solar cell panel 24 is composed of a photovoltaic device set formed by electrically connecting a plurality of the photovoltaic devices 20 and the covering material 21 for sealing the photovoltaic device set.

In addition, the junction box 26 and the output cable 27 for outputting generated power outside are provided on the non-light-receiving surface of the solar cell module.

The individual constituent elements of the solar cell module according to the embodiment will be described below in detail.

(Photovoltaic Device)

Examples of such a photovoltaic device 20 according to the present invention include a single-crystal silicon photovoltaic device, a polycrystalline silicon photovoltaic device, a microcrystal silicon photovoltaic device, an amorphous silicon photovoltaic device, and a polycrystalline compound photovoltaic device. A typical photovoltaic device suitably used out of those devices includes a transparent electrode layer, a photoelectric conversion layer, a back reflecting layer, and a back electrode layer from a light-receiving surface side, and electrodes for outputting generated electricity are provided in part. The transparent electrode layer, the photoelectric conversion layer, the back reflecting layer, and the back electrode layer will be described below in detail.

The transparent electrode layer transmits light as an electrode of light incidence side and also serves as an antireflection film by optimising the film thickness. The transparent electrode layer is required to have high transmittance and low electrical resistance at a sorbable wavelength range of the photoelectric conversion layer. Preferable examples of a material used for the layer include conductive oxide such as In₂O₃, SnO₂, ITO (In₂O₃+SnO₂), ZnO, CdO, Cd₂SnO₄, TiO₂, Ta₂O₅, Bi₂O₃, MoO₃, or NaₓWO₃ or a mixture of the materials mentioned above. Suitably used as a method of forming the transparent electrode layer is a sputtering method with sputtering gas which contains a small amount of oxygen.

The photoelectric conversion layer converts light to electricity. It is possible to use one of the following materials as the material of the photoelectric conversion layer: V-group elements such as Si, C, and Ge, IV-group element alloys such as SiGe and SiC, III-V-group compounds such as GaAs, InSb, GaP, GaSb, InP, and InAs, II-VI-group compounds such as ZnSe, ZnS, CdS, CdSe, and CdTe, and I-III-VI-group compounds such as CuInSe. However, the material of the photoelectric conversion layer is not limited to such materials. The photoelectric conversion layer forms at least one pair of a pn junction, a pin junction, a hetero junction, or a Schottky barrier. Moreover, examples of a suitable method of forming the photoelectric conversion layer include various kind of chemical vapor deposition (referred to as CVD) methods such as a microwave plasma CVD method, very high frequency (referred to as VHF) plasma CVD method, and radio-frequency (referred to as RF) plasma CVD method.

The back reflecting layer functions as a light reflecting layer which reflects light, which could not be absorbed in the photoelectric conversion layer, on the photoelectric conversion layer again. It is possible to use one of the following materials as the material of the back reflecting layer: metals such as Au, Ag, Cu, Al, Ni, Fe, Cr, Mo, W, Ti, Co, Ta, Nb, and Zr, or alloys such as stainless steel. However, of those materials, metal having high reflectivity such as Al, Cu, Ag, or Au is particularly preferable.

The back electrode layer functions as a collecting electrode for collecting electric charge generated on the non-light-receiving surface side of the photoelectric conversion layer. Examples of a material of the back electrode layer include metals such as Al, Au, Ag, Cu, Ti, Ta, and W. However, the material of the back electrode layer is not limited to such materials. Preferable examples of a formation method for the back electrode layer include the chemical vapor deposition method and the sputtering method. In addition, suitably used as the back electrode layer is a conductive substrate which functions as a supporting substrate for supporting each of the layers so that the layers are not damaged by forces exerted from outside. It is possible to use one of the following materials as a specific material of the conductive substrate: metals such as Fe, Ni, Cr, Al, Mo, Au, Nb, Ta, V, Ti, Pt, and Pb, or a thin film of alloys of these metals and its complex. However, the material of the conductive substrate is not limited to such materials.

(Photovoltaic Device Set)

A photovoltaic device set denotes a series connection body or a parallel connection body of photovoltaic devices formed by electrically connecting a plurality of photovoltaic devices.

(Solar Cell Panel)

In the present invention, a solar cell panel denotes a generating body in which a single photovoltaic device or the aforementioned photovoltaic device set is sealed with a covering material having environment resistance.

(Covering Material)

The covering material is composed of a surface member which is arranged on the light-receiving surface side of the photovoltaic devices, a back member which is arranged on the non-light-receiving surface side, and a sealing material which is arranged between the surface member and the back member.

Suitably used as a material of the surface member is glass or a fluoride polymer film. However, the material of the surface member is not limited to such materials. Examples of a fluoride polymer include polyvinylidene fluoride (referred to as PVDF), polyvinyl fluoride (referred to as PVF), ethylene-tetrafluoroethylene (referred to as ETFE) copolymer, polychlorotrifluoroethylene (referred to as PCTFE), chlorotrifluoroethylene-ethylene (referred to as ECTFE) copolymer, parfluoro(alkyl vinyl ether)-tetrafluoroethylene (referred to as PFA) copolymer, hexafluoropropylene-tetrafluoroethylene (referred to as FEP) copolymer, tetrafluoroethylene-hexafluoropropylene-vinylidene fluoride copolymer, and a complex of two or more of these materials. The ETFE as one of such materials is preferably used because of suitable surface member for the solar cell module from the viewpoint of transparency as well as simultaneous pursuit of weather resistance and mechanical strength. Furthermore, one of the reasons why the EPFE is selected is that the ETFE is easy to generate a reaction product on the film surface by means of discharge treatment.

The back member is used to protect the photovoltaic devices, to prevent moisture from entering, and to maintain electrical insulation from outside. Preferable as a material of the back member is a material that can maintain sufficient electrical insulation, is superior in long durability, and can resist thermal expansion or thermal contraction. Examples of suitably used materials include a polyvinyl fluoride film, nylon film, polyethylene terephthalate film, and glass plate.

The sealing material is used for sealing the photovoltaic devices, for preventing the elements from a severe external environment such as temperature change, humidity, or shock, and for maintaining adherence between the surface member or the back member and the devices. Examples of a material of the sealing material include an ethylene-vinyl accetate (referred to as EVA) copolymer resin, an ethylene-methyl acrylate (referred to as EMA) copolymer resin, an ethylene-ethyl acrylate (referred to as EEA) copolymer resin, an ethylene-methacrylic acid (referred to as EMAA) copolymer resin, an ionomer resin, and a polyvinyl butyral resin. However, of these materials, the EVA resin is suitably used because it has balanced physical properties for use in solar cells, for example, weather resistance, adhesiveness, filling property, heat resistance, cold resistance, and impact resistance.

(Reinforcing Member)

The reinforcing member 22 functions to provide mechanical strength to the solar cell panel 24 so that the photovoltaic devices are not subject to damage by external stress during or after installation. The reinforcing member 22 according to the present invention includes at least the installation surface 22b for installing the solar cell panel 24 and the perpendicular portions 22a provided perpendicular to the installation surface 22b. In such a structure, the perpendicular portions 22a function to restrain flexure of the installation surface 22b due to any external stress. In addition, the provision of the turnback portion 22c on the end portion of the above-mentioned perpendicular portion 22a is desirable to further restrain the flexure.

Examples of a suitable material of the reinforcing member 22 include a galvanized steel plate, steel plate including weather resistance material such as a fluorocarbon resin or polyvinyl chloride, and a stainless steel plate. In addition, a metal sheet or plate is particularly preferable because the perpendicular portion 22a can be formed with ease by bending, but it is not limited to such materials.

Furthermore, the above-mentioned perpendicular portions 22a are provided at least on the end portion on the long side or the end portion on the short side of the reinforcing member 22, where at the adjacent two reinforcing members 22, 22, one perpendicular portion 22a of the reinforcing member 22 is in contact with the other perpendicular portion 22a of the reinforcing member 22. In this structure, when external stress is exerted on the solar cell module, the perpendicular portions 22a provided on the reinforcing member 22 tend to be deformed; however, the perpendicular portions of the adjacent two reinforcing members 22 are in contact with each other and consequently deformation of one perpendicular portion 22a is restrained by the other perpendicular portion 22a, thereby improving flexibility of the solar cell module against the external stress.

When a solar cell panel 24 is installed on an installation surface of one plate of reinforcing member having many perpendicular portions, similarly to the present invention, the solar cell module can improve mechanically. However, size per plate of reinforcing member becomes larger, so that it requires a large-scale processing device with less productivity. Moreover, one plate of reinforcing member having many perpendicular portions causes infiltration of moisture at the interface between the solar cell panel 24 and the reinforcing member, and thus the moisture tends to accumulate on the perpendicular portions. This is because the perpendicular portion is bent into a V-shape and hence the bottom of the perpendicular portion becomes closed. Consequently, the moisture infiltrated has nowhere to escape and stays there for long time, thereby causing the reinforcing member to rust or to accelerate hydrolysis of the covering material. In the present invention, since a plurality of the reinforcing members are placed apart from each other, the moisture infiltrated at the interface between the solar cell panel 24 and the reinforcing member 22 can be drained to the outside inma short time.

Furthermore, in a method of providing L-shaped angle on a tabular reinforcing member, perpendicular portions can also be provided on the back of the solar cell module, and therefore such a structure can improve mechanical strength similarly to the present inrvention. The above-mentioned angle, however, is required to have adhesive face with respect to the reinforcing member other than the perpendicular portions. In the present invention, the reinforcing member 22 itself has the perpendicular portion 22a, thus the adhesive face mentioned above is not required and the weight can be reduced by the adhesive face while similar mechanical strength is maintained.

(Frame)

Preferably, the solar cell module can be directly fixed to the base or other supporting member by screws without using fixing tool when the frame 23 is provided on the end portion of the solar cell module. The frame 23 can use a channel-shaped aluminum frame, for example, which has a concave portion (insertion portion) for inserting the solar cell panel 24.

The above-mentioned frame 23 may be provided only on either the end portion on the long side or the end portion on the short side of the solar cell module, and accordingly this structure enables further reduction in weight of the solar cell module. Furthermore, when the reinforcing member 22 is inserted into the frame 23 so that the above-mentioned perpendicular portion 22a is arranged perpendicularly to the frame 23, preferably, the attachment of the reinforcing members becomes more secure.

In addition, provision of the insertion portion in the frame 23 for receiving the solar cell panel 24 and the installation surface 22b of the above-mentioned reinforcing member 22 permits to support the solar cell panel 24 and the reinforcing member 22. Furthermore, provision of a cutout in the insertion portion of the frame 23 for inserting the perpendicular portions 22a of the reinforcing member 22 permits to connect the reinforcing member 22 with the frame 23 with ease.

When a bypass diode provided to the solar cell panel 24 is placed in the insertion portion of the frame 23, breakage due to external stress degradation or solar insolation can be prevented.

(Adhesive/Double-Side Adhesive Tape)

The adhesive or double-side adhesive tape is used to fix the solar cell panel 24 to the installation surface 22b of the reinforcing member 22, and required to have excellent weather resistance and excellent water resistance. As a specific material of the adhesive or double-side adhesive tape, there are, for example, a silicon adhesive, an epoxy adhesive, an acryl double-side adhesive tape, and butyl double-side adhesive tape.

A method of producing a solar cell module including the plurality of reinforcing members 22 with perpendicular portions on the back of the solar cell panel 24 in which the photovoltaic devices 20 for performing photoelectric conversion are sealed with a covering material according to an embodiment of the present invention, includes the steps of: forming the solar cell panel 24; forming the installation surface 22b of the solar cell panel 24 by placing the plurality of reinforcing members 22 with the perpendicular portions 22a,; and installing the solar cell panel 24 on the installation surface 22b.

In the above-mentioned method of producing the solar cell module, it is preferable that the step of forming the solar cell panel 24 includes a step of sealing a photovoltaic device set which is composed of the photovoltaic device 20 or the plurality of photovoltaic devices 20 that are electrically connected with a covering material. Moreover, it is preferable to include a step of inserting the frame 23 into the end portion of the solar cell module after the step of installing the solar cell panel 24 on the installation surface 22b. Furthermore, in the step of inserting the frame 23 into the end portion of the solar cell module, the frame 23 may be provided on only the end portion on the long side or the end portion on the short side of the solar cell module.

As described above, according to this embodiment, the solar cell module can improve its mechanical strength without increasing the thickness of the reinforcing member 22 and can reduce its weight. Moreover, since the conventional reinforcing member is made of one flat plate, local stress concentration is caused in the reinforcing member when the solar cell module is applied with external stress, while such a solar cell module composed of the plurality of reinforcing members 22 can relieve stress concentration. Furthermore, this structure is superior in productivity to a solar cell module having a single plate of reinforcing member with a plurality of perpendicular portions.

In addition, the present invention is effective for not only the solar cell module with large area but also the solar cell module with small area.

Examples of the present invention will be described in detail below, but the present invention is not limited to those examples.

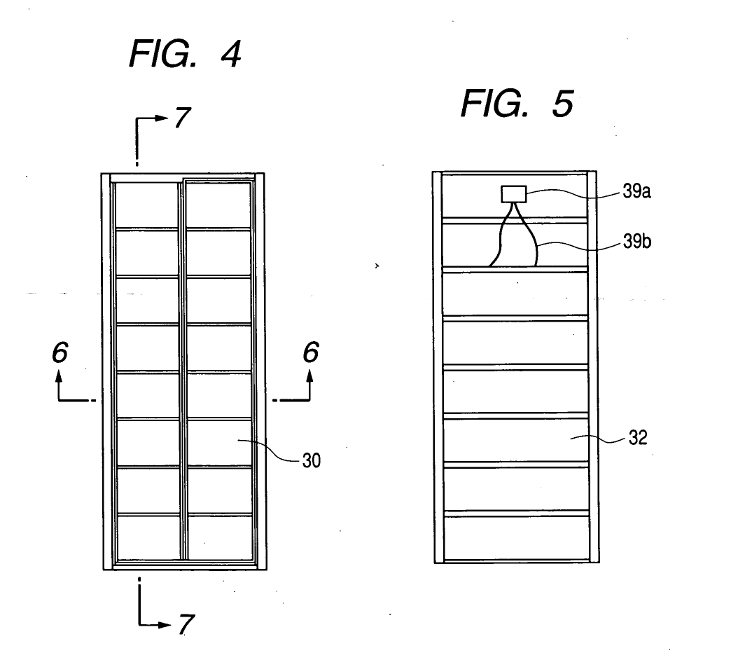

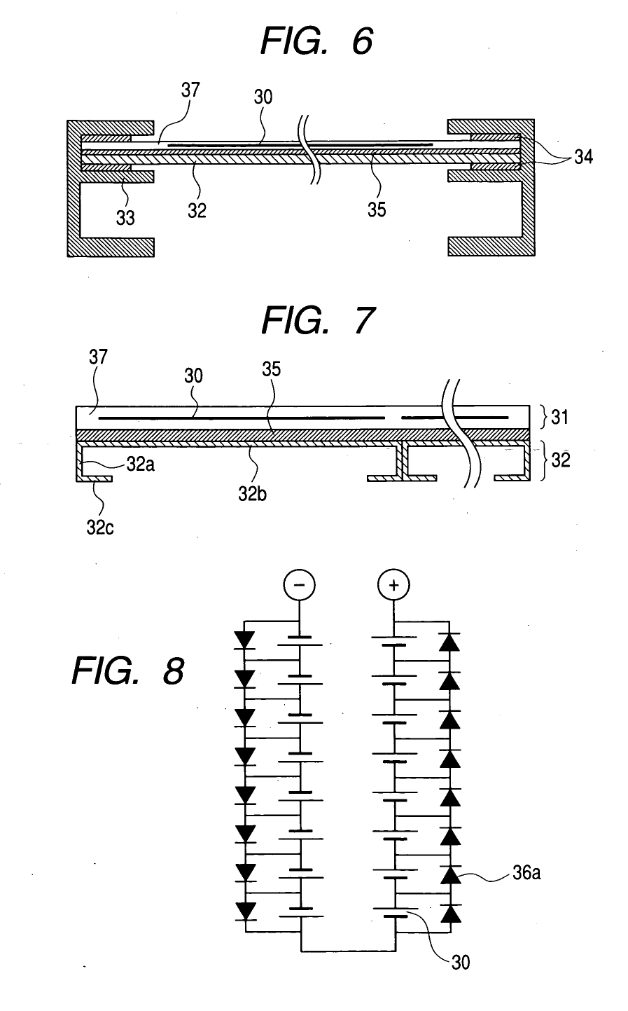

FIG. 4 is a top plan view seen from a light-receiving surface side showing a solar cell module according to the example of the present invention, and FIG. 5 is a rear view seen from a non-light-receiving surface side showing the solar cell module according to the example of the present invention. Moreover, FIG. 6 is a cross-sectional view taken along the line 6-6 in FIG. 4, and FIG. 7 is a cross-sectional view taken along the line 7-7 in FIG. 4. Furthermore, FIG. 8 is an electrical connection diagram for explaining a solar cell module according to the example of the present invention. In these figures, reference numeral 30 denotes a photovoltaic device, 31 denotes a solar cell panel, 32 denotes a reinforcing member, 32a denote a perpendicular portion, 32b denotes an installation surface, 32c denotes a turnback portion, 33 denotes a frame, 34 denotes a filler, 35 denotes an adhesive, 36a denotes a bypass diode, and 37 denotes a covering material.

As shown in the figures, a solar cell module according to this example includes a plurality of the reinforcing members 32 which are in contact with the back of the solar cell panel 31 in which the photovoltaic device 30 for performing a photoelectric conversion is sealed with the covering material, each reinforcing member 32 provides the perpendicular portion 32a formed on the opposed end portions along a width direction of the solar cell panel 31 as well as extended with respect to an installation portion of a structure such as a roof or a wall, and the frame 33 is provided on the opposed end portions along a longitudinal direction of the solar cell panel 24 perpendicular to the perpendicular portion 32a of the reinforcing member 32.

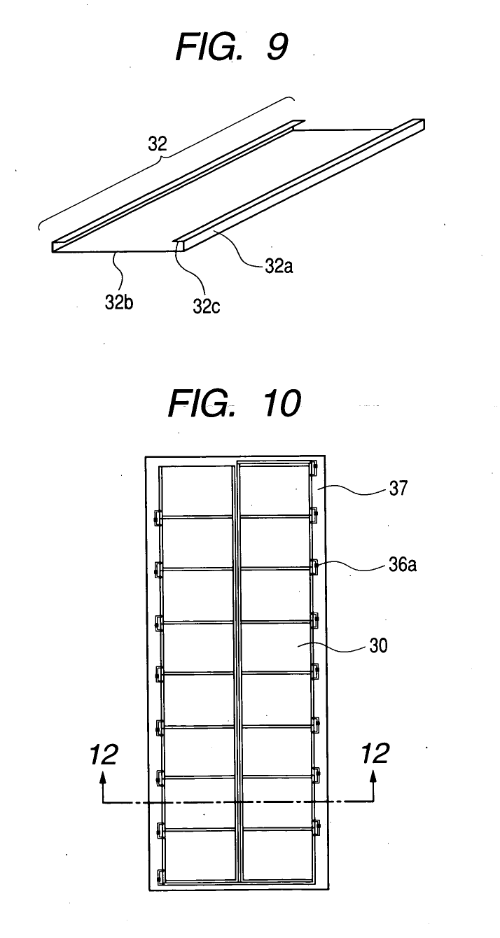

FIG. 9 is a perspective view showing a reinforcing member used in a solar cell module according to this example. As shown in the figures, the solar cell module according to this example includes the eight reinforcing members 32 having the perpendicular portion 32a, the installation surface 32b, and the turnback portion 32c. The reinforcing member 32 is made of galbarium steel plate in which the perpendicular portion 22a formed by a roller former is respectively provided on each of the end portions on the long side of the reinforcing member 32. The eight reinforcing members 32 are placed so that the perpendicular portions 32a of the adjacent reinforcing members 32 are in contact with each other, and each of the installation surfaces 32b of the respective reinforcing members 32 forms the installation surface 32b for installing the solar cell panel 31. The solar cell panel 31 is fixed on the installation surface 32b by the adhesive 35 such as silicone sealant.

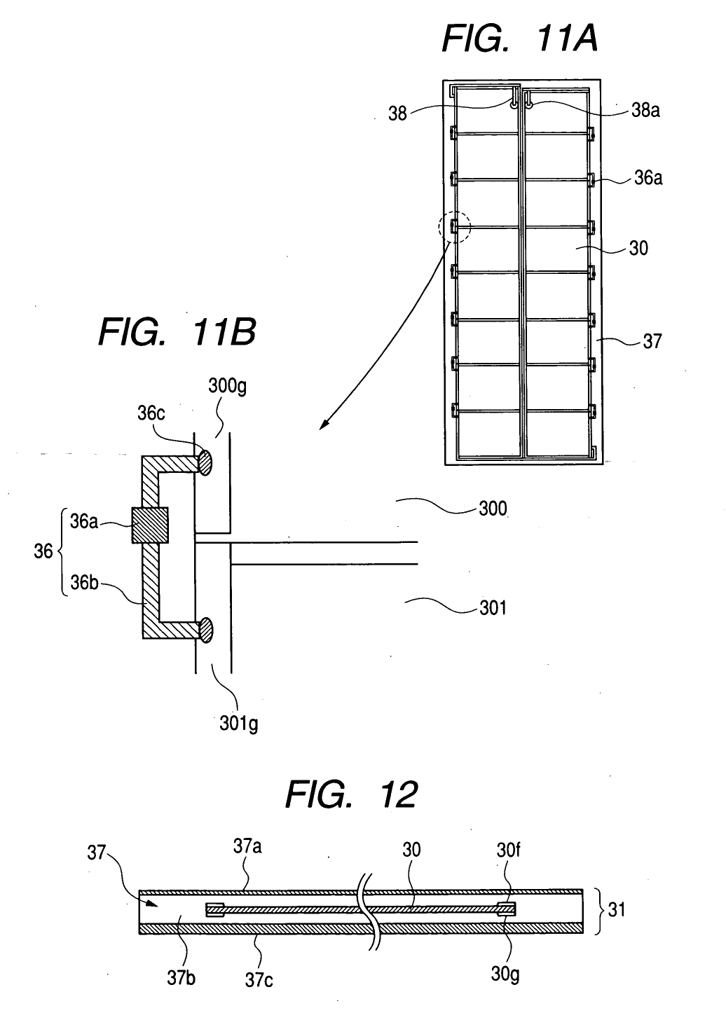

FIG. 10 is a top plan view seen from a light-receiving surface side showing the solar cell panel according to this example, FIG. 11A is a rear view seen from a non-light-receiving surface side, and FIG. 11B is an enlarged view showing a main part encircled in FIG. 11A. In these figures, reference numeral 30 denotes the photovoltaic device, 36 denotes a bypass connection portion, 36a denotes a bypass diode, 36b denotes a diode terminal, 36c denotes a solder, 37 denotes a covering material, 38 denotes a lead electrode, 38a denotes an exposed portion of the lead electrode, 300 and 301 denote a photovoltaic device, and 300g and 301g denote an electrode.

The solar cell panel according to this example constitutes a photovoltaic device set in which sixteen amorphous silicon-based photovoltaic devices 30 are connected in series. In such a structure, a gap between the photovoltaic devices is set to 2 mm in the longitudinal direction and is set to 3 mm in the width direction perpendicular to the longitudinal direction.

When the solar cell panel is shadowed partly, a reverse bias voltage is applied to a photovoltaic device, which is in non-power-generation condition due to no exposure to the sun light, through a load from a photovoltaic device that is connected in series to the photovoltaic device in power-generation condition, thereby causing the photovoltaic device to be damaged, and therefore the bypass diode 36a is provided at each of the photovoltaic devices on the end portions of the solar cell panel. As shown in FIG. 11B, the above-mentioned bypass diode 36a is electrically connected through the diode terminal 36b to the electrode 300g which is provided on the non-light-receiving surface of the photovoltaic device 300 on one side and to the electrode 301g which is provided on the non-light-receiving surface of the adjacent photovoltaic device 301 with the solder 36c.

Moreover, FIG. 12 is a cross-sectional view taken along the line 12-12 in FIG. 10. In FIG. 12, reference numeral 30 denotes the photovoltaic device, 30f and 30g denote the electrode, 31 denotes the photovoltaic device, 37 denotes the covering material, 37a denotes a surface member, 37b denotes a sealing material, and 37c denotes a back member.

As shown in the figure, each photovoltaic device 30 constituting the photovoltaic device set mentioned above is protected by the covering material 37. An ETFE film is arranged as the surface member 37a on the light-receiving surface side of the above-mentioned photovoltaic device set, a polyethylene terephthalate (referred to as PET) film is arranged as the back member 37c on-the non-light-receiving surface side, and these films and the photovoltaic device 30 are bonded by EVA as the sealing material 37b.

As shown in FIG. 11A, the above-mentioned photovoltaic device set is provided with the lead electrode 38 for taking out the generated electricity, and a part of the lead electrode 38a is exposed from the covering material 37 in the non-light-receiving surface of the solar cell panel.

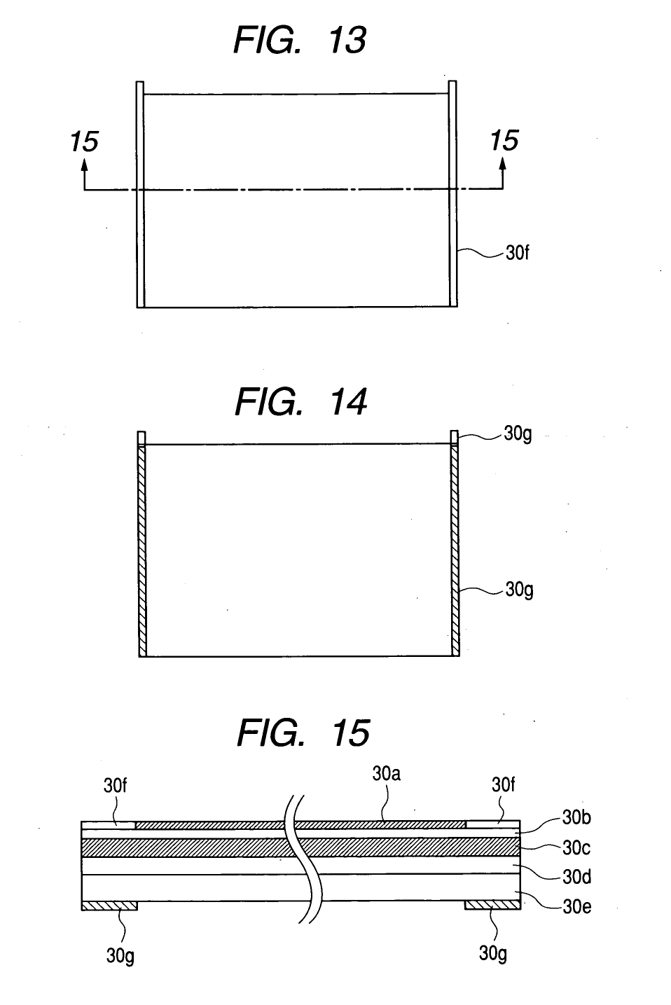

Now, FIG. 13 is a top plan view seen from a light-receiving surface side showing a photovoltaic device according to this example, and FIG. 14 is a rear view seen from a non-light-receiving surface side showing a photovoltaic device according to this example. Moreover, FIG. 15 is a cross-sectional view taken along the line 15-15 in FIG. 13. In these figures, reference symbol 30a denotes a resin layer, 30b denotes a transparent electrode layer, 30c denotes a photoelectric conversion layer, 30d denotes a back reflecting layer, 30e denotes a back electrode layer, 30f denotes a positive electrode, and 30g denotes a negative electrode.

As shown in the figures, the photovoltaic device 30 is composed of at least the resin layer 30a, the transparent electrode layer 30b, the photoelectric conversion layer 30c, the back reflecting layer 30d, and the-back electrode layer 30e from the light-receiving surface side. The resin layer 30a is made of acrylic urethane resin. The transparent electrode layer 30b is made of ITO. The photoelectric conversion layer 30c is made of P-I-N-based amorphous silicon. The back reflecting layer 30d is made of ZnO and AI. The back electrode layer 30e is made of stainless steel. Furthermore, the positive electrode 30f made of silver plated copper foil is provided on the light-receiving surface of the transparent electrode layer 30b, and the negative electrode 30g made of copper foil is provided on the non-light-receiving surface of the back electrode layer 30e.

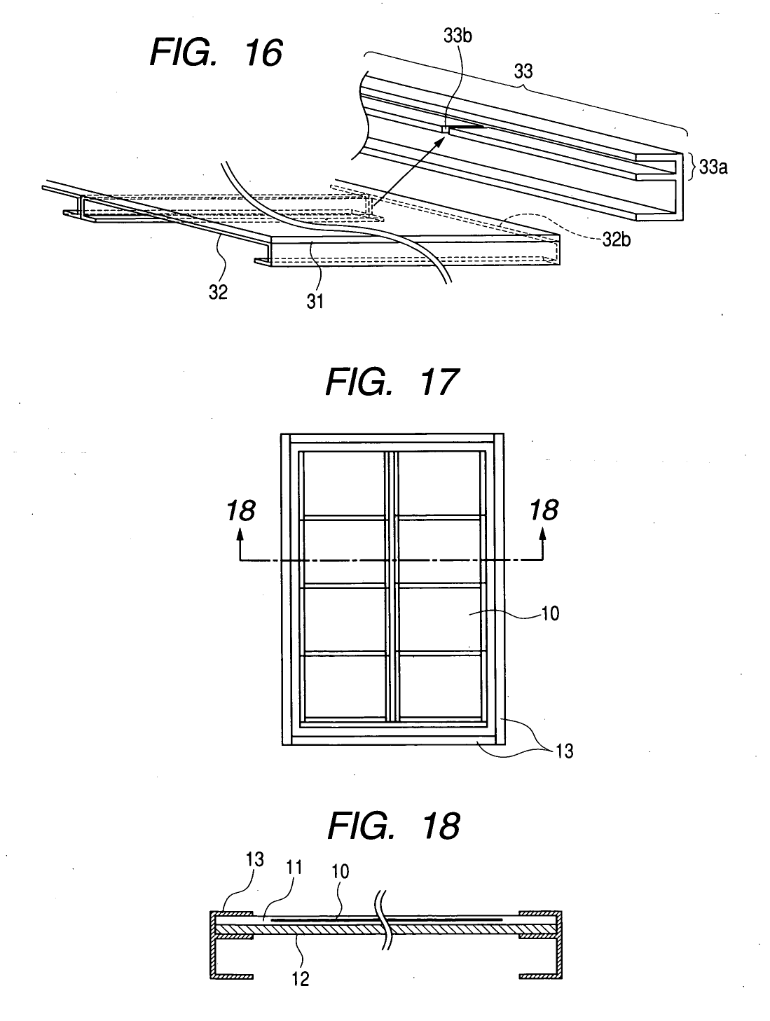

In addition, FIG. 16 is a perspective view showing an assembling structure of a solar cell module according to this example. In FIG. 16, reference numeral 31 denotes a solar cell panel, 32 denotes a reinforcing member, 32a denotes perpendicular portions, 33 denotes a frame, 33a denotes an insertion portion, and 33b denotes a cutout. As shown in the figure, the frame 33 made of aluminum alloy is provided on the end portion on the long side of the solar cell module. The frame 33 includes the insertion portion 33a for inserting the reinforcing member 32 inside, and also includes the cutout 33b on the part of the insertion portion 33a. The installation surface 32b of the reinforcing member 32 and the solar cell panel 31 are inserted into the above-mentioned insertion portion 33a, and the perpendicular portion 32a of the reinforcing member 32 is inserted into and fixed to the above-mentioned cutout 33b. An adhesive such as silicone sealant which is not shown in the figure is filled in the insertion portion 33a of the frame 33 for preventing the reinforcing member 32 from falling off.

Moreover, the above-mentioned bypass diodes 36a are put in the insertion portion 33a of the above-mentioned frame so that the bypass diode 36a may not be damaged by an external stress.

Furthermore, two through holes each having a diameter of 15 mm, which are not shown in the figure, are provided on a part of the reinforcing member 32, and the positions of these through holes conform with those of the above-mentioned lead electrodes 38 exposed from the solar cell panel 31 to fix them by adhering. As shown in FIG. 5, those through holes are covered by the junction box 39a made of denatured polyphenylether (referred to as PPE). The output cable 39b is soldered to the lead electrode 38a and is stuck out through the junction box 39a. Moreover, an adhesive such as silicone sealant is filled in the junction box 39a.

Now, a method of producing a solar cell module of this example will be described.

A method of producing a solar cell module of this example includes the steps of: forming a solar cell panel; forming an installation surface by placing a reinforcing member with a perpendicular portion; installing the solar cell panel on the installation surface; providing a frame on an end portion of the solar cell module; and fixing an output cable and a junction box, and each of the steps will be described below in-detail.

The step of forming a solar cell panel includes a work of forming a photovoltaic device set in which a plurality of photovoltaic devices are connected in series, a work of providing a bypass diode on each of the photovoltaic devices, a work of providing a lead electrode on the photovoltaic device set, and a work of sealing the photovoltaic device set with a covering material.

In order to form the photovoltaic device set, eight pieces of photovoltaic devices are arranged first in series with a 2 mm gap between adjacent devices, and the electrodes provided on the light-receiving surface of the adjacent photovoltaic device on one side are electrically connected sequentially to the electrodes provided on the non-light-receiving surface on the other side with solder, thereby forming a series connection body of photovoltaic devices. Next, the above-mentioned series connection bodies are placed in two rows spaced with a 3 mm gap, and a positive electrode of an end portion of the series connection body on one side and a negative electrode of an end portion of the series connection body on the other side are electrically connected to a single copper foil to form a photovoltaic device set. In this configuration, the above-mentioned copper foil is 5.5 mm wide and 0.2 mm thick.

The work of providing the bypass diode is to form a diode with terminals first by soldering the diode terminals made of L-shaped copper foil to a Schottky barrier type diode. Then, the above-mentioned diode with terminals is arranged on the corner portion of each photovoltaic device. At that time, the diode with terminals is arranged so as to be placed on the end portion on the long side of the photovoltaic device set. Finally, in each of the diodes with terminals, a diode terminal on one side is electrically connected to the electrode provided on the non-light-receiving surface of the photovoltaic device, and a diode terminal on the other side is electrically connected to the electrode provided on the non-light-receiving surface of the adjacent photovoltaic device, respectively. In such a structure, when there exists no adjacent photovoltaic device, a diode terminal on the other side is electrically connected to an extended portion of the electrode provided on the light-receiving surface of the photovoltaic device.

The work of providing the lead electrode on the photovoltaic device set is carried out by: electrically connecting a copper foil to the positive electrode and the negative electrode of the photovoltaic device set; and leading the above-mentioned copper foil to the non-light-receiving surface side of the photovoltaic device set.

The work of sealing the photovoltaic device set with the covering material is performed using a lamination apparatus of a double vacuum system. The covering material is composed of the PET film (thickness:50 μm), the EVA film (thickness:400 μm) on the PET film, the photovoltaic device set (the light-receiving surface is placed upward) on the EVA film, the EVA film (thickness: 400 μm) on the light-receiving surface of the photovoltaic device set, and the ETFE film (thickness:25 μm) on the EVA sheet.

A stacked structure composed of the covering materials and the photovoltaic devices is put into an oven at 150° C. and heated through vacuum heating for 40 minutes, and consequently each covering material and the photovoltaic device set are integrated. After that, the sealing work is completed when the stacked structure is taken out from the oven and cooled at room temperature.

In such a configuration, the PET film and EVA film provided on the non-light-receiving surface side of the lead electrode each have a through hole with a diameter of 20 mm and are positioned with the lead electrode in laminating. Thus, the lead electrode is exposed after laminating.

Next, the eight reinforcing members provided with the perpendicular portion formed by a roller former are placed so that respective perpendicular portions are in contact with the perpendicular portion of the adjacent reinforcing member, and therefore the installation surface of the solar cell panel is formed. At that time, each of the reinforcing members is fixed temporarily with tape so as not to be misaligned. In such a configuration, one of the eight reinforcing members has two through holes of a 15 mm diameter.

The solar cell panel is fixed on the installation surface of the reinforcing member with an adhesive such as silicone sealant. First, silicone sealant is applied to the installation surface in a longitudinal direction in four rows. Next, the solar cell panel is installed on the installation surface and pressed sufficiently so that the adhesive spreads. At that time, it should be confirmed that the exposed portion of the lead electrode provided on the solar cell panel and the through holes provided in the reinforcing member are aligned at the same positions.

After the silicone sealant existing at the interface between the solar cell panel and the installation surface of the reinforcing member has been hardened, the work of providing the frame on the end portion on the long side of the solar cell module is carried out. First, the silicone sealant is applied to the end portion of short side of the non-light-receiving surface side of each reinforcing member. Next, the solar cell panel and the reinforcing member are inserted into the insertion portion of the frame and the perpendicular portion of the reinforcing member is inserted into the cutout, respectively.

Finally, the work of fixing the output cable and the junction box is carried out. The above-mentioned junction box is composed of a frame body and a cover body, and the frame body has a through hole for taking out an output cable. First, the frame body is fixed to the non-light-receiving surface of the reinforcing member with a double-side adhesive tape. Next, the output cable is inserted into the through hole of the frame body and the output cable and the lead electrode are electrically connected. After that, the work is completed when silicone resin is filled in the frame body and the cover body is fixed.

This application claims priority from Japanese Patent Application No. 2003-413072 filed Dec. 11, 2003, which is hereby incorporated by reference herein.

1. A solar cell module, comprising:
a solar cell panel in-which a photovoltaic device for performing photoelectric conversion is sealed with a covering material;
a plurality of reinforcing members which are in contact with a back of the solar cell panel;
a perpendicular portion formed on an opposed end portion of each of the reinforcing members at least along one of a longitudinal direction and a width direction of the solar cell panel as well as extended with respect to an installation portion of a structure; and
a frame provided on an opposed end portion of the solar cell panel perpendicular to the perpendicular portion of the reinforcing member.

2. The solar cell module according to claim 1, wherein the perpendicular portion of the reinforcing member is formed by bending.

3. The solar cell module according to claim 1, wherein the perpendicular portion of the reinforcing member on one side is in contact with the perpendicular portion of the reinforcing member on the other side in two adjacent reinforcing members.

4. The solar cell module according to claim 1, wherein the solar cell panel comprises a photovoltaic device set which is obtained by electrically connecting at least one photovoltaic device.

5. The solar cell module according to claim 1, wherein the frame is provided on only one of the end portion on the long side and end portion on the short side of the solar cell module.

6. The solar cell module according to claim 1, wherein the frame comprises an insertion portion into which the solar cell panel is inserted.

7. The solar cell module according to claim 6, wherein a part of the insertion portion comprises a cutout into which the perpendicular portion of the reinforcing member is inserted.

8. The solar cell module according to claim 6, wherein the solar cell panel comprises at least one bypass diode and the bypass diode is inserted into the insertion portion of the frame.

9. The solar cell module according to claim 1, wherein the solar cell panel and the reinforcing member are fixed with one of an adhesive and a double-side adhesive tape.

10. The solar cell module according to claim 1, wherein the solar cell panel comprises a light-receiving surface and a non-light-receiving surface and at least one of the light-receiving surface and the non-light-receiving surface is sealed with the covering material.

11. A method of producing a solar cell module which comprises a plurality of reinforcing members with perpendicular portions on a back of a solar cell panel in which photovoltaic devices for performing photoelectric conversion are sealed with a covering material, the method comprising the steps of:
forming the solar cell panel;
forming an installation surface of the solar cell panel by placing a plurality of the reinforcing members with the perpendicular portions; and
installing the solar cell panel on the installation surface.

12. The method of producing a solar cell module according to claim 11, wherein the step of forming the solar cell panel comprises a step of sealing a photovoltaic device set which is obtained by electrically connecting at least one photovoltaic device.

13. The method of producing a solar cell module according to claim 11, further comprising a step of inserting the frame into the end portion of the solar cell module after the step of installing the solar cell panel on the installation surface.

14. The method of producing a solar cell module according to claim 13, wherein in the step of inserting the frame into the end portion of the solar cell module, the frame is provided on only one of the end portion on the long side and end portion on the short side of the solar cell module.
